(19) United States
(12) Patent Application Publication
(10) Pub. No.: US 2025/0240977 A1
(43) Pub. Date: Jul. 24, 2025

(54) HIGH BANDWIDTH MEMORY

(71) Applicant: Samsung Electronics Co., Ltd., Suwon-si (KR)

(72) Inventors: CHI WOO LEE, Suwon-si (KR); HYUNSOO CHUNG, Suwon-si (KR)

(21) Appl. No.: 18/797,535

(22) Filed: Aug. 8, 2024

(30) Foreign Application Priority Data
Jan. 22, 2024 (KR) 10-2024-0009462

(51) Int. Cl. H10B 80/00; H01L 23/367; H01L 23/498; H01L 25/065

(52) U.S. Cl. CPC H10B 80/00; H01L 23/367; H01L 23/49816; H01L 25/0657; H01L 2225/06541

(57) ABSTRACT

A high bandwidth memory according to an example embodiment includes: a base die; a memory stack on the base die, the memory stack including a plurality of stacked memory dies, and the memory stack having a first region defined by dividing a horizontal plane of the memory stack, and a second region on the horizontal plane surrounding the first region; a dummy die on the memory stack; and a plurality of bumps between the memory stack and the dummy die, the plurality of bumps including a plurality of first bumps disposed in the first region and a plurality of second bumps disposed in the second region, a pitch of neighboring second bumps among the plurality of second bumps different from a pitch of neighboring first bumps among the plurality of first bumps.

### CROSS-REFERENCE TO RELATED APPLICATION

This application claims priority to Korean Patent Application No. 10-2024-0009462 filed in the Korean Intellectual Property Office on Jan. 22, 2024, the entire contents of which are incorporated herein by reference.

### BACKGROUND OF THE INVENTION

### (a) Field of the Invention

The present disclosure relates to a high bandwidth memory.

### (b) Description of the Related Art

The semiconductor industry is pursuing miniaturization, weight reduction, and thinness of semiconductor packages mounted on electronic devices, while simultaneously implementing high speed, multi-function, and high capacity in response to demands for miniaturization and weight reduction for electronic devices. Therefore, the need for a packaging technology that may store more data and transmit data at a higher speed is increasing, and a high bandwidth memory (HBM) capable of achieving a high bandwidth by stacking more dynamic random-access memories (DRAMs) on a substrate having the same area is well known as such a packaging technology.

The high bandwidth memory (HBM) is manufactured by disposing a memory stack formed by stacking the DRAMs on a buffer die. As the number of DRAMs in the memory stack increases, it is possible to implement a high-performance high bandwidth memory (HBM). However, in a case where the number of stacked DRAMs increases beyond a certain level, a surface topography of each DRAM accumulated from a lower portion of the memory stack to an upper portion of the memory stack becomes larger, and as a result, a stack void may occur at an interface between DRAM dies at the upper portion of the memory stack.

In addition, in a case where the number of stacked DRAMs increases beyond a certain level, warpage may occur in the memory stack or heat may be accumulated inside the memory stack, degrading the performance of the high bandwidth memory (HBM).

Therefore, there is a need to develop a packaging technology that may address the problems in the high bandwidth memory (HBM).

### SUMMARY OF THE INVENTION

In the high bandwidth memory (HBM) including the memory stack in which memory dies are stacked, a thickness of an uppermost memory die in the memory stack may be the same as a thickness of each of the remaining memory dies in the memory stack, a dummy die may be disposed on the memory stack, the uppermost memory die of the memory stack and the dummy die may be connected using bumps, and an insulating member may be disposed between the uppermost memory die of the memory stack and the dummy die.

Considering a location where heat is concentrated in the memory stack or a warpage characteristic of the memory stack, a pitch of first bumps positioned in a central region of the memory stack and a pitch of second bumps around the central region may be designed to be different from each other.

According to some example embodiments, a high bandwidth memory includes: a base die; a memory stack on the base die, the memory stack including a plurality of stacked memory dies, and the memory stack having a first region defined by dividing a horizontal plane of the memory stack, and a second region in the horizontal plane surrounding the first region; a dummy die on the memory stack; and a plurality of bumps between the memory stack and the dummy die, the plurality of bumps including a plurality of first bumps disposed in the first region and a plurality of second bumps disposed in the second region, a pitch of neighboring second bumps among the plurality of second bumps different from a pitch of neighboring first bumps among the plurality of first bumps.

According to some example embodiments, a high bandwidth memory includes: a base die; a memory stack on the base die, the memory stack including a plurality of stacked memory dies and a plurality of interconnection structures alternating with the plurality of stacked memory dies, and the memory stack having a first region defined by dividing a horizontal plane of the memory stack, and a second region in the horizontal plane surrounding the first region; a dummy die on the memory stack; a plurality of bumps between the memory stack and the dummy die, the plurality of bumps including a plurality of first bumps disposed in the first region, and a plurality of second bumps disposed in the second region, a pitch of neighboring second bumps among the plurality of second bumps different from a pitch of neighboring first bumps among the plurality of first bumps; and a molding material covering the memory stack, the dummy die, and the plurality of bumps on the base die.

According to some example embodiments, a high bandwidth memory includes: a base logic die; a plurality of core dies stacked on the base logic die, an uppermost core die of the plurality of core dies having a first region defined by dividing a horizontal plane of the uppermost core die, and a second region in the horizontal plane surrounding the first region; a heat dissipation structure on the uppermost core die; a plurality of bumps between the uppermost core die and the heat dissipation structure, a plurality of bumps including a plurality of first bumps on the first region, and a plurality of second bumps on the second region, a pitch of neighboring second bumps among the plurality of second bumps different from a pitch of neighboring first bumps among the plurality of first bumps; and a molding material covering the plurality of core dies, the heat dissipation structure, and the plurality of bumps on the base logic die.

A dummy die having a larger size than a size of the uppermost memory die of the memory stack may be disposed on the memory stack, and an insulating member may be disposed between the uppermost memory die of the memory stack and the dummy die. As a result, it is possible to prevent formation of a stack void at an interface between the memory dies.

The uppermost memory die of the memory stack and the dummy die may be connected by the bumps, and the pitch of the first bumps positioned in a central region on the memory stack may be designed to be different from the pitch of the second bumps positioned around the central region to alleviate warpage of the memory stack and effectively dissipate heat generated in the memory stack.

### BRIEF DESCRIPTION OF THE DRAWINGS

FIG. 1 is a cross-sectional view illustrating a high bandwidth memory according to an example embodiment.

FIG. 2 illustrates a footprint of the high bandwidth memory according to an example embodiment of FIG. 1.

FIG. 3 is a cross-sectional view illustrating a high bandwidth memory according to an example embodiment.

FIG. 4 illustrates a footprint of the high bandwidth memory according to an example embodiment of FIG. 3.

FIG. 5 is a cross-sectional view illustrating a high bandwidth memory according to an example embodiment.

FIG. 6 is a cross-sectional view illustrating a high bandwidth memory according to an example embodiment.

FIG. 7 is a cross-sectional view illustrating a high bandwidth memory according to an example embodiment.

### DETAILED DESCRIPTION

Hereinafter, example embodiments of the present disclosure will be described in detail with reference to the accompanying drawings so that those skilled in the art to which the present disclosure pertains may easily practice the invention. However, the invention may be modified in various different forms, and is not limited to example embodiments provided in the present specification.

Portions unrelated to the description will be omitted in the drawings in order to describe the present disclosure, and similar components will be denoted by the same reference numerals throughout the present specification.

In addition, since sizes and thicknesses of the respective components illustrated in the drawings are arbitrarily illustrated for convenience of explanation, the present disclosure is not necessarily limited to those illustrated in the drawings.

Throughout the present specification, when a portion or component is referred to as being “connected to” another portion or component, it includes a case in which the portion or component and the other portion or component are “indirectly connected to” each other with a different component interposed therebetween as well as a case in which the portion or component and the other portion or component are “directly connected to” each other. However, items described as “contacting” each other, or “in contact with” each other, or using any other form of “contact,” are directly connected (i.e., touching) at their point of contact. In addition, throughout the present specification, unless explicitly described to the contrary, the word “comprise” and variations such as “comprises” or “comprising”, will be understood to imply the inclusion of stated elements but not the exclusion of any other elements.

In addition, it will be understood that when an element such as a layer, a film, a region, or a plate is referred to as being “on” another element, it may be directly on the other element or intervening elements may also be present. In contrast, when an element is referred to as being “directly on” another element, there are no intervening elements present. In addition, when an element is referred to as being “on” a reference element, it may be positioned above or beneath the reference element, and is not necessarily positioned on the reference element in an opposite direction to gravity.

Further, throughout the specification, the word “plan view” refers to a view when a target is viewed from the top, and the word “cross-sectional view” refers to a view when a cross section of a target taken along a vertical direction is viewed from the side. Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Items described in the singular herein may be provided in plural, as can be seen, for example, in the drawings. Thus, the description of a single item that is provided in plural should be understood to be applicable to the remaining plurality of items unless context indicates otherwise.

Hereinafter, a high bandwidth memory (HBM) 100 according to an example embodiment will be described with reference to the drawings.

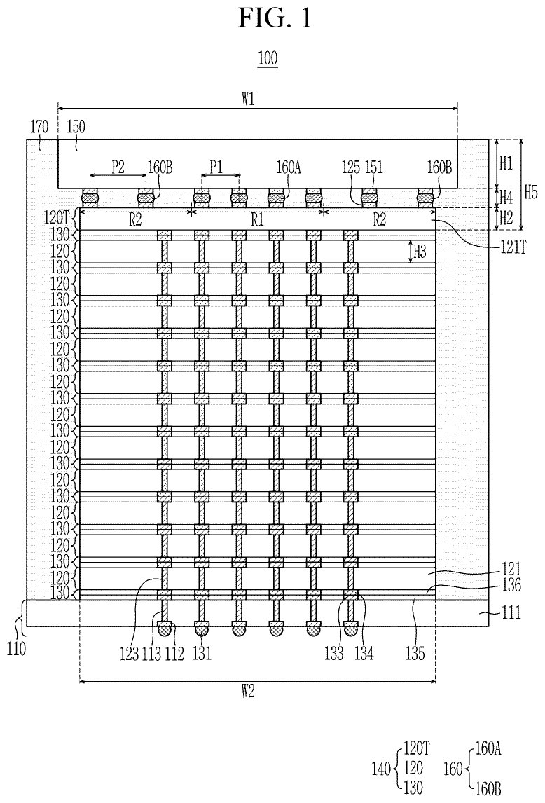

FIG. 1 is a cross-sectional view illustrating the high bandwidth memory (HBM) 100 according to an example embodiment.

Referring to FIG. 1, a high bandwidth memory (HBM) 100 may include a buffer die (a base die or a base logic die) 110, a memory stack 140 including stacked memory dies (core dies) 120 and interconnection structures 130 alternating with the memory dies 120, a dummy die 150, connection members 160, and a molding material 170. The high bandwidth memory (HBM) 100 according to the present disclosure may include the memory stack 140 in which 12 memory dies are stacked. However, the present disclosure is not limited thereto, and the high bandwidth memory (HBM) 100 may include a memory stack 140 in which various numbers of memory dies 120 are stacked. For example, the high bandwidth memory (HBM) 100 may include a memory stack 140 in which 4, 8, 16, or 24 memory dies are stacked.

The high bandwidth memory (HBM; 100) may be a high-performance three-dimensional (3D) stacked dynamic random-access memory (DRAM). The high bandwidth memory (HBM) 100 may be manufactured using a through silicon via (TSV) technology (TSVs 123, generally described as through substrate vias) in which one memory stack 140 is formed by vertically stacking the memory dies 120 including DRAM circuits, thousands of fine holes vertically penetrating through the stacked memory dies 120 are formed in the memory dies 120, and the holes are filled with a conductive material for electrical connection.

The high bandwidth memory (HBM) 100 has multiple memory channels through the memory stack 140 formed by vertically stacking the memory dies 120 and thus may achieve low latency and high bandwidth simultaneously as compared with a DRAM product according to the related art. In addition, the total area occupied by individual DRAMs on a printed circuit board (PCB) may be reduced, which provides an advantage in terms of high bandwidth per unit area and power consumption reduction.

The buffer die 110 may be disposed at a bottom of the high bandwidth memory (HBM) 100 and may be disposed between the memory stack 140 and an external device (not illustrated). When data is exchanged between devices with different data processing speeds, processing units, and usage times, data loss may occur due to differences in data processing speed, processing unit, and usage time between the devices. In order to prevent such loss, the buffer die 110 may be disposed between the memory stack 140 and the external device (not illustrated) to temporarily store information in the buffer die 110 as data is transferred to and from the memory stack 140 and the external device (not shown)). When transmitting data to or receiving data from the memory stack 140, the buffer die 110 arranges the order of the data and passes the data in order.

The buffer die 110 may include a die base 111, a channel (not illustrated) within the die base 111, connection pads 112, first through silicon vias 113, and connection members 131 under the die base 111. Each of the connection pads 112 may be disposed between a first through silicon via 113 and a connection member 131. Each of the connection pads 112 may electrically connect a first through silicon via 113 to a connection member 131. In an example embodiment, the connection pad 112 may comprise at least one of copper, aluminum, tungsten, nickel, gold, tin, titanium, and an alloy thereof. Each of the first through silicon vias 113 may be disposed between a first bonding pad 133 of the interconnection structure 130 and a connection pad 112. Each of the first through silicon vias 113 may electrically connect a first bonding pad 133 of an interconnection structure 130 to a connection pad 112. In an example embodiment, the first through silicon via 113 may comprise at least one of tungsten, aluminum, copper, and an alloy thereof. Each of the connection members 131 may be disposed between a first through silicon via 113 and the external device (not illustrated). Each of the connection members 131 may be an external connection terminal that electrically connects the first through silicon via 113 to the external device (not illustrated). In an example embodiment, the connection member 131 may be a micro bump or a solder ball. In an example embodiment, the connection member 131 may comprise at least one of tin, silver, lead, nickel, copper, and an alloy thereof. As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, or an electrically insulative protective layer, etc.) is not electrically connected to that component. Moreover, items that are “directly electrically connected,” to each other are electrically connected through one or more passive elements, such as, for example, wires, pads, internal electrical lines, through vias, etc.

The memory stack 140 may be disposed on the buffer die 110. The memory stack 140 may include the memory dies 120 and the interconnection structures 130. The memory dies 120 may each include a die base 121, memory channels (not illustrated) within the die base 121, and second through silicon vias 123. In an example embodiment, the memory die 120 may be a DRAM. Each of the second through silicon vias 123 may be disposed between a first bonding pad 133 and a second bonding pad 134. Each of the second through silicon vias 123 may electrically connect the second bonding pad 134 to the first bonding pad 133. In an example embodiment, the second through silicon via 123 may comprise at least one of tungsten, aluminum, copper, and an alloy thereof.

Among the memory dies 120, an uppermost memory die (uppermost core die) 120T may include a die base 121T, memory channels (not illustrated) within the die base 121T, and bonding pads 125 on the die base 121T. In an example embodiment, the uppermost memory die 120T may be a DRAM. The uppermost memory die 120T may not include the second through silicon vias 123. No additional memory dies or core dies 120 are disposed above the uppermost memory die/core die 120T. The uppermost memory die 120T may have a vertical thickness H2 that is the same as a vertical thickness H3 of the memory die 120. Each of the bonding pads 125 may have a structural function for bonding each of the connection members 160 to the die base 121T of the uppermost memory die 120T, and may not have an electrical function. The bonding pad 125 is a dummy pad. Therefore, in one embodiment, no signals are transmitted from the dummy die 150 to the memory stack 140 through the bonding pad 125 or from the memory stack 140 to any circuitry or active circuit components within the dummy die 150 through the bonding pad 125. The bonding pads 125 may be electrically isolated from circuitry within the uppermost memory die 120T, for example, by contacting the uppermost memory die 120T at an electrically insulating layer of the uppermost memory die 120T.

The interconnection structures 130 may be disposed between the buffer die 110 and the memory stack 140 and between neighboring memory dies 120 among the memory dies 120. The interconnection structure 130 may bond the memory stack 140 and the buffer die 110 to each other by hybrid bonding. The interconnection structure 130 may bond neighboring memory dies 120 among the memory dies 120 to each other by the hybrid bonding.

The hybrid bonding may be performed using the interconnection structure 130 between the buffer die 110 and the memory stack 140, or between neighboring memory dies 120 among the memory dies 120. The hybrid bonding may be a method of bonding two devices by fusing the same materials of the two devices using bonding properties of the same materials. Here, the term “hybrid” means bonding two devices by two different types of bonding, for example, a first type of metal-metal bonding and a second type of non-metal-non-metal bonding. With the hybrid bonding, input/output (I/O) with a fine pitch may be formed.

Each of the interconnection structures 130 may include the first bonding pads 133, the second bonding pads 134, a first silicon insulating layer 135, and a second silicon insulating layer 136. The first bonding pads 133 may be disposed on an upper surface of the buffer die 110 or on an upper surface of each of the memory dies 120 except for the uppermost memory die 120T. The first bonding pads 133 may penetrate through the first silicon insulating layer 135. The second bonding pads 134 may be disposed on a lower surface of each of the memory dies 120 and on the first bonding pads 133. The second bonding pads 134 may penetrate through the second silicon insulating layer 136. The first silicon insulating layer 135 may be disposed on the upper surface of the buffer die 110 or on the upper surface of each of the memory dies 120 except for the uppermost memory die 120T. The first silicon insulating layer 135 may surround and insulate the first bonding pads 133. The second silicon insulating layer 136 may be disposed on the lower surface of each of the memory dies 120 and on the first silicon insulating layer 135. The second silicon insulating layer 136 may surround and insulate the second bonding pads 134.

The first bonding pad 133 may be directly bonded to the second bonding pad 134 by metal-metal hybrid bonding. Metal bonding is made at an interface between the first bonding pad 133 and the second bonding pad 134 by the metal-metal hybrid bonding. In an example embodiment, the first bonding pad 133 and the second bonding pad 134 comprise copper. In another example embodiment, the first bonding pad 133 and the second bonding pad 134 may be formed of any metallic material to which the hybrid bonding is applicable.

The first bonding pad 133 and the second bonding pad 134 may be formed of the same material, and thus, the interface between the first bonding pad 133 and the second bonding pad 134 may disappear after the hybrid bonding. The buffer die 110, the memory stack 140, and the memory dies 120 may be electrically connected to each other through the first bonding pads 133 and the second bonding pads 134.

The first silicon insulating layer 135 may be directly bonded to the second silicon insulating layer 136 by non-metal-non-metal hybrid bonding. Covalent bonding may be made at an interface between the first silicon insulating layer 135 and the second silicon insulating layer 136 by the non-metal-non-metal hybrid bonding. In an example embodiment, the first silicon insulating layer 135 and the second silicon insulating layer 136 may comprise an inorganic material. In an example embodiment, the first silicon insulating layer 135 and the second silicon insulating layer 136 comprise silicon oxide or tetraethyl orthosilicate (TEOS)-forming oxide. In an example embodiment, the first silicon insulating layer 135 and the second silicon insulating layer 136 comprise SiO₂. In an example embodiment, the first silicon insulating layer 135 and the second silicon insulating layer 136 may be formed of silicon nitride, silicon oxynitride, or other suitable dielectric materials. In an example embodiment, the first silicon insulating layer 135 and the second silicon insulating layer 136 comprise SiN or SiCN.

The first silicon insulating layer 135 and the second silicon insulating layer 136 may be formed of the same material, and the interface between the first silicon insulating layer 135 and the second silicon insulating layer 136 may disappear after the hybrid bonding.

The memory stack 140 may be formed by stacking the memory dies 120 from the memory die 120 disposed on the buffer die 110 to the uppermost memory die 120T. A surface topography of each memory die 120 is accumulated from the bottom to the top of the memory stack 140 due to such a stacked structure. Therefore, a stack void may be formed at an interface between the memory dies 120 positioned at an upper portion of the memory stack 140. The stack void formed in this way may cause a significant increase in cumulative surface topography of the memory die 120 stacked on the stack void. Due to such a vicious cycle, the cumulative surface topography of the memory stack 140 may significantly increase, and more stack voids may be formed. The increase in cumulative surface topography of the memory stack 140 and the stack voids may deteriorate etch uniformity during the subsequent through silicon via formation process and cause bonding defects during the hybrid bonding process, which may lead to a large yield loss. The stack void may be confirmed from an image obtained by inspection using scanning acoustic tomography (SAT) equipment.

As a result of testing a high bandwidth memory (HBM) according to the related art, in a case where 7 memory dies 120 were stacked, almost no stack voids were formed, but in a case where 8 memory dies 120 were stacked, a ratio of the area of the stack void to the area of the memory die was about 10%. Further, in a case where 12 memory dies 120 were stacked, a ratio of the area of the stack void to the area of the memory die was about 20%. Therefore, it may be seen that the stack void is formed after eight memory dies 120 are stacked, and that the stack void rapidly increases as more memory dies 120 are stacked on the eight memory dies 120.

The dummy die 150 may be disposed on the memory stack 140. The dummy die 150 may be disposed on the uppermost memory die 120T. The dummy die 150 may be bonded to the uppermost memory die 120T by the connection members 160. The dummy die 150 may have a vertical thickness H1 larger than the vertical thickness H2 of the uppermost memory die 120T and the vertical thickness H3 of the memory die 120. The dummy die 150 may have a horizontal width W1 equal to or larger than a horizontal width W2 of the uppermost memory die 120T and the memory die 120. Therefore, the dummy die 150 having a size (e.g., horizontal width) larger than that of the uppermost memory die 120T and the memory die 120 may be disposed on the memory stack 140, and the dummy die 150 applies pressure to the memory stack 140 to prevent formation of the stack void at the interface between the memory dies 120 positioned at the upper portion of the memory stack 140 in which the memory dies 120 having a small thickness are stacked.

The dummy die 150 may be electrically isolated from other components. The dummy die 150 may be a heat dissipation structure. The dummy die 150 may be surrounded by the molding material 170. An upper surface of the dummy die 150 may be exposed from the molding material 170. In an example embodiment, the dummy die 150 may be formed of a conductive material with a high thermal conductivity. In an example embodiment, the dummy die 150 may comprise copper, aluminum, gold, silver, iron, or stainless steel (SUS). In an example embodiment, the dummy die 150 may be formed of a silicon material with a higher thermal conductivity as compared to the molding material 170. The dummy die 150 may be a solid, monolithic piece of material, or may have other structures, such as a core formed of one material and a coating or outer surrounding layer formed of a different material. In one embodiment, the dummy die 150 does not include any active circuit devices formed therein. The dummy die 150 may be electrically isolated from circuitry in the memory stack 140 due to, for example, connecting only to an insulating surface of the uppermost core die 120T of the memory stack 140. In this way, by implementing the dummy die 150 as the heat dissipation structure, heat generated within the memory stack 140 may be dissipated to the outside through the dummy die 150. As a result, a thermal characteristic of the high bandwidth memory (HBM) 100 may be improved.

The dummy die 150 may include connection pads 151. Each of the connection pads 151 may be bonded to the connection member 160. Each of the connection pads 151 may be electrically isolated from other components within the dummy die 150, so that in one embodiment, no signals are transmitted from the dummy die to the memory stack 140 or from the memory stack 140 to any circuitry or active circuit components within the dummy die 150.

The connection members 160 may be disposed between the memory stack 140 and the dummy die 150. The connection members 160 may bond the dummy die 150 to the memory stack 140. Each of the connection members 160, which may be connection terminals, may be disposed between a connection pad 151 of the dummy die 150 and a bonding pad 125 of the uppermost memory die 120T. The connection members 160 may be electrically isolated from other components. The connection members 160 may be electrically isolated from the memory stack 140. The connection members 160 may be surrounded by the molding material (which may be a molded under-fill (MUF)) 170.

The connection members 160 may include a set of first connection members 160A and a set of second connection members 160B. The uppermost memory die 120T (or the memory stack 140) may have a first region R1 and a second region R2 defined by dividing a plane of the uppermost memory die 120T. The first region R1 may be a central region of the uppermost memory die 120T. The second region R2 may be a peripheral region around the first region R1 (e.g., surrounding the first region R1 in a plan view). The first connection members 160A may be positioned in the first region R1. The first connection members 160A may be arranged in relation to each other with a first pitch P1. The second connection members 160B may be positioned in the second region R2. The second connection members 160B may be arranged in relation to each other with a second pitch P2. The first pitch P1 may be larger than the second pitch P2. In an example embodiment, each connection member 160 may be a bump.

Bumps having a certain size or more may be disposed between the uppermost memory die 120T and the dummy die 150 to prevent formation of the stack void at the boundary between the memory dies 120 positioned at the upper portion of the memory stack 140 in which the memory dies 120 having a small thickness are stacked.

In addition, the first pitch P1 between the first connection members 160A positioned in the first region R1 on the memory stack 140 and the pitch between the second connection members 160B positioned in the second region R2 may be set to be different from each other to alleviate warpage of the memory stack 140 or effectively dissipate heat generated from the memory stack 140.

The molding material 170 may be disposed on the buffer die 110 and cover the memory stack 140, the dummy die 150, and the connection members 160. The molding material 170 may serve to protect and insulate the memory stack 140, the dummy die 150, and the connection members 160. The molding material 170 may be a MUF and cover the connection members 160 between the memory stack 140 and the dummy die 150. In an example embodiment, the MUF may have a vertical thickness H4 of about 20 μm to about 40 μm. In an example embodiment, the molding material 170 may be an epoxy molding compound (EMC).

As the molding material 170 is disposed between the memory stack 140 and the dummy die 150, it is possible to prevent cracks by weakening a stress at portions prone to cracks according to a warpage characteristic of the memory stack 140.

In an example embodiment, a sum H5 of the thickness H1 of the dummy die, the thickness H2 of the uppermost memory die 120T, and the thickness H4 of the MUF may be about 100 μm to about 200 μm. In an example embodiment, the vertical height H5 from a lower surface of the uppermost memory die 120T to the upper surface of the dummy die may be about 100 μm to about 200 μm.

In the high bandwidth memory (HBM) according to the related art, the uppermost memory die of the memory stack has a thickness larger than that of a general memory die. According to the present disclosure, the sum H5 of the thickness H1 of the dummy die, the thickness H2 of the uppermost memory die 120T, and the thickness H4 of the MUF may correspond to the thickness of the uppermost memory die of the memory stack according to the related art. Accordingly, the high bandwidth memory (HBM) 100 according to the present disclosure does not have a size (e.g., a height) larger than that of the high bandwidth memory (HBM) according to the related art.

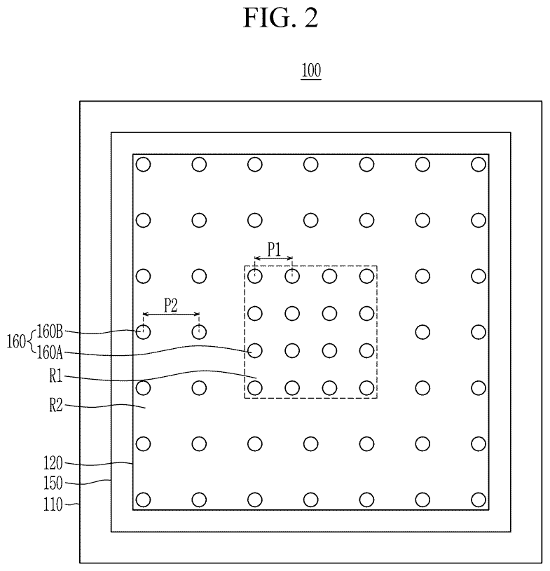

FIG. 2 illustrates a footprint of the high bandwidth memory (HBM) 100 according to an example embodiment of FIG. 1.

Referring to FIG. 2, the memory stack 140 may have the first region R1 and the second region R2 defined by dividing the plane of the memory stack 140. The first region R1 may be the central region of the memory stack 140. The first region R1 is indicated by a dotted line. The second region R2 may be the peripheral region around the first region R1. The dummy die 150 may have a planar size that is equal to or larger than a planar size of the memory stack 140 and is equal to or smaller than a planar size of the buffer die 110.

The first connection members 160A may be positioned in the first region R1. The first connection members 160A may be arranged with the first pitch P1. In an example embodiment, the first pitch P1 between neighboring first connection members 160A among the first connection members 160A in each of a first horizontal direction and a second horizontal direction perpendicular to the first horizontal direction may be about 5 μm to about 10 μm. The second connection members 160B may be positioned in the second region R2. The second connection members 160B may be arranged with the second pitch P2. In an example embodiment, the second pitch P2 between neighboring second connection members 160B among the second connection members 160B in each of the first horizontal direction and the second horizontal direction may be about 30 μm to about 40 μm.

When the memory stack 140 has a warpage characteristic in which the first region R1 rises higher than the second region R2, the first connection members 160A disposed in the first region R1 may be arranged with a smaller pitch, and the second connection members 160B disposed in the second region R2 may be arranged with a larger pitch. The first connection members 160A and the second connection members 160B are arranged such that the stress applied to the memory stack 140 by the first connection members 160A and the second connection members 160B offsets the warpage of the memory stack 140. With such arrangement, the warpage of the memory stack 140 may be alleviated. In addition, since more heat is generated in the first region R1, which is the central region of the memory stack 140, the generated heat may be effectively dissipated by arranging first connection members 160A in the first region R1.

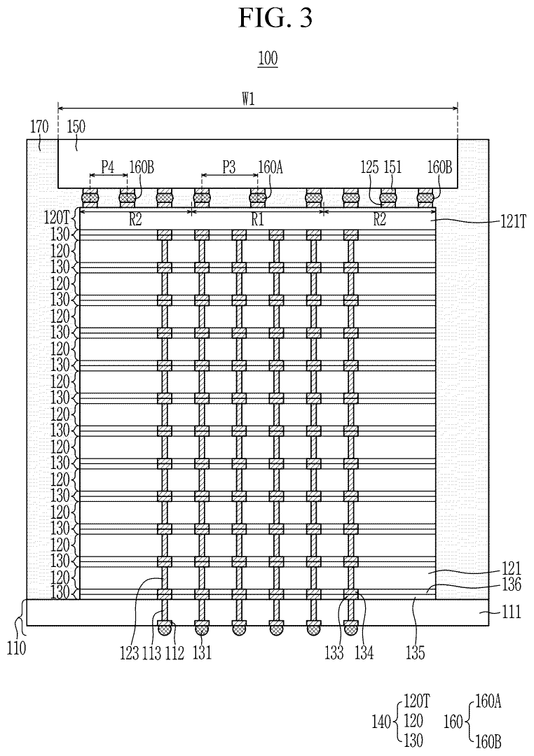

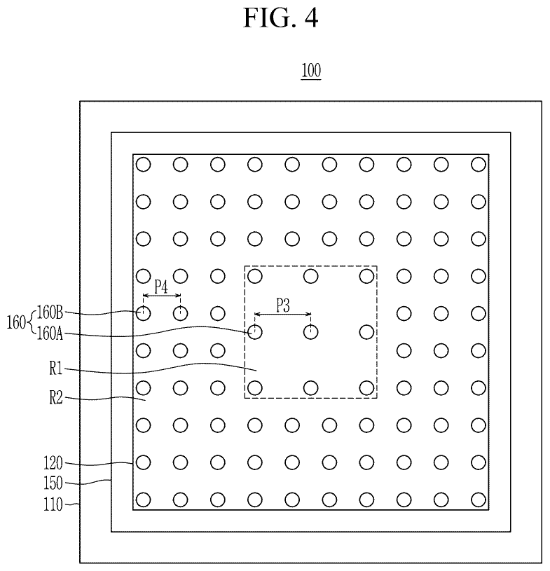

FIG. 3 is a cross-sectional view illustrating a high bandwidth memory (HBM) 100 according to an example embodiment. FIG. 4 illustrates a footprint of the high bandwidth memory (HBM) 100 according to an example embodiment of FIG. 3.

Referring to FIGS. 3 and 4, a memory stack 140 may have a first region R1 and a second region R2 defined by dividing a plane of the memory stack 140. The first region R1 may be a central region of the memory stack 140. The first region R1 is indicated by a dotted line. The second region R2 may be a peripheral region around the first region R1. First connection members 160A may be positioned in the first region R1. The first connection members 160A may be arranged with a third pitch P3. In an example embodiment, the third pitch P3 between neighboring first connection members 160A among the first connection members 160A may be about 30 μm to about 40 μm. Second connection members 160B may be positioned in the second region R2. The second connection members 160B may be arranged with a fourth pitch P4. In an example embodiment, the fourth pitch P4 between neighboring second connection members 160B among the second connection members 160B may be about 5 μm to about 10 μm.

When the memory stack 140 has a warpage characteristic in which the first region R1 descends lower than the second region R2, the first connection members 160A disposed in the first region R1 may be arranged with a larger pitch, and the second connection members 160B disposed in the second region R2 may be arranged with a smaller pitch. With such arrangement, the warpage of the memory stack 140 may be alleviated.

In FIGS. 3 and 4, a configuration other than the arrangement of the first and second connection members 160A and 160B are the same as those described regarding FIGS. 1 and 2. Accordingly, the contents described in FIGS. 1 and 2 may be equally applied to the configuration other than the arrangement of the first and second connection members 160A and 160B in FIG. 3.

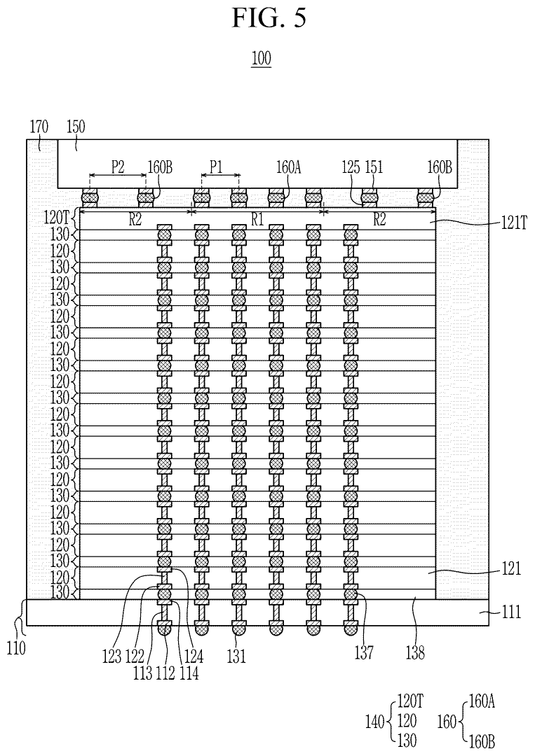

FIG. 5 is a cross-sectional view illustrating a high bandwidth memory (HBM) 100 according to an example embodiment.

Referring to FIG. 5, a buffer die 110 may include first lower connection pads 112, first through silicon vias (TSVs) 113, and first upper connection pads 114.

Each of the first lower connection pads 112 may be disposed between a first through silicon via (TSV) 113 and a connection member 131. Each of the first lower connection pads 112 may electrically connect the first through silicon via (TSV) 113 to the connection member 131. The connection member 131 may be an external connection terminal. Each of the first through silicon vias 113 may be disposed between a first lower connection pad 112 and a first upper connection pad 114. Each of the first through silicon vias 113 may electrically connect the first upper connection pad 114 to the first lower connection pad 112. Each of the first upper connection pads 114 may be disposed between a first through silicon via (TSV) 113 and a connection member 137. The connection member 137 may be, for example, an interconnection terminal such as a solder bump or ball. Each of the first upper connection pads 114 may electrically connect a connection member 137 to a first through silicon via (TSV) 113. In an example embodiment, the first lower connection pad 112 and the first upper connection pad 114 may each comprise at least one of copper, aluminum, tungsten, nickel, gold, tin, titanium, and an alloy thereof. In an example embodiment, the first through silicon via 113 may comprise at least one of tungsten, aluminum, copper, and an alloy thereof.

The memory stack 140 may include memory dies 120 and interconnection structures 130. Each of the memory dies 120 of the memory stack 140 may include second lower connection pads 122, second through silicon vias (TSVs) 123, and second upper connection pads 124.

Each of the second lower connection pads 122 may be disposed between a second through silicon via (TSV) 123 and a connection member 137. Each of the second lower connection pads 122 may electrically connect a second through silicon via (TSV) 123 to a connection member 137. Each of the second through silicon vias 123 may be disposed between a second lower connection pad 122 and a second upper connection pad 124. Each of the second through silicon vias 123 may electrically connect the second upper connection pad 124 to the second lower connection pad 122. Each of the second upper connection pads 124 may be disposed between a second through silicon via (TSV) 123 and a connection member 137. Each of the second upper connection pads 124 may electrically connect a connection member 137 to a second through silicon via (TSV) 123. In an example embodiment, the second lower connection pad 122 and the second upper connection pad 124 may each comprise at least one of copper, aluminum, tungsten, nickel, gold, tin, titanium, and an alloy thereof. In an example embodiment, the second through silicon via 123 may comprise at least one of tungsten, aluminum, copper, and an alloy thereof.

The interconnection structure 130 of the memory stack 140 may include the connection members 137 and an insulating member 138. Each memory die 120 of the memory stack 140 may be bonded by flip chip bonding. Each of the connection members 137 may be disposed between the lower connection pad 122 and the upper connection pad 124. Each of the connection members 137 may electrically connect the upper connection pad 124 to the lower connection pad 122. In an example embodiment, the connection member 137 may comprise at least one of tin, silver, lead, nickel, copper, or an alloy thereof. In an example embodiment, the connection member 137 may include a micro bump.

The insulating member 138 may surround and protect the connection members 137 between the buffer die 110 and a neighboring memory die 120 and between neighboring memory dies 120. In an example embodiment, the insulating member 138 may be an insulating layer and may include a non-conductive film (NCF). In an example embodiment, the insulating member 138 may comprise an organic material. In an example embodiment, the insulating member 138 may comprise an epoxy resin, an acrylic resin, a silica filler, and an additive. In an example embodiment, the additive may include phenol.

In FIG. 5, a configuration other than the described configuration is the same as that described in FIGS. 1 and 2. Accordingly, in FIG. 5, the contents described in FIGS. 1 and 2 may be equally applied to the configuration other than the described configuration.

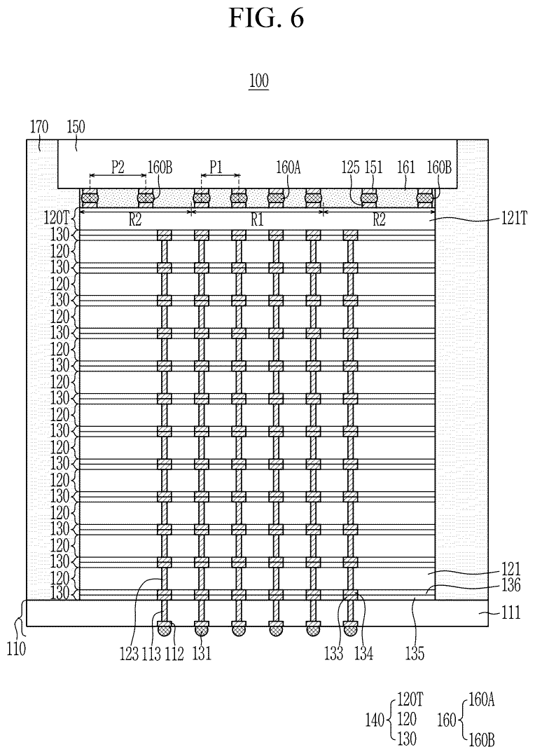

FIG. 6 is a cross-sectional view illustrating a high bandwidth memory (HBM) 100 according to an example embodiment.

Referring to FIG. 6, the high bandwidth memory (HBM) 100 may include an insulating member 161 between a memory stack 140 and a dummy die 150. The insulating member 161 may surround and protect connection members 160 between the memory stack 140 and the dummy die 150. In an example embodiment, the insulating member 161 may include a non-conductive film (NCF). In an example embodiment, the insulating member 161 may include a non-conductive paste (NCP). In an example embodiment, the insulating member 161 may include a capillary under-fill (CUF). The insulating member 161 may be formed of a different material as and/or in a different process from the molding material 170.

Considering a warpage characteristic of the memory stack 140, the insulating member 161 may be disposed between the memory stack 140 and the dummy die 150. When the insulating member 161 comprising a different type of material from that of a molding material 170 is disposed between the memory stack 140 and the dummy die 150, it is possible to prevent cracks by weakening a stress at portions prone to cracks according to the warpage characteristic of the memory stack 140.

In FIG. 6, a configuration other than the insulating member 161 is the same as that described in FIGS. 1 and 2. Accordingly, in FIG. 6, the contents described in FIGS. 1 and 2 may be equally applied to the configuration other than the insulating member 161.

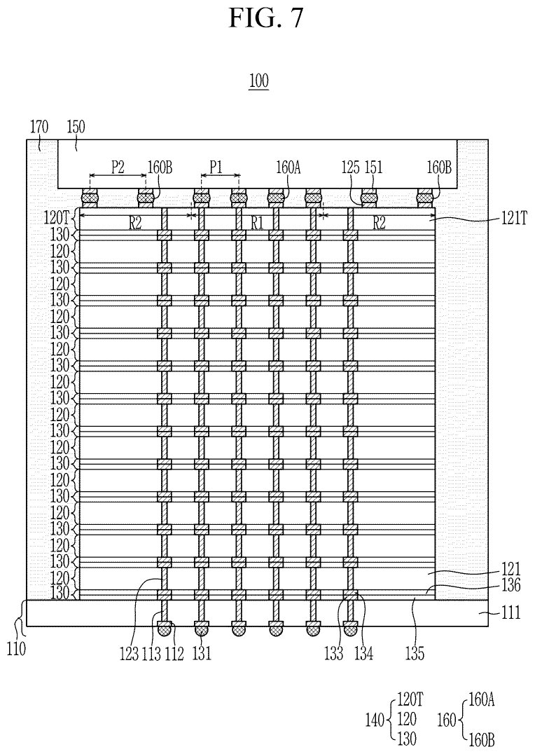

FIG. 7 is a cross-sectional view illustrating a high bandwidth memory (HBM) 100 according to an example embodiment.

Referring to FIG. 7, an uppermost memory die 120T may include second through silicon vias 123. The second through silicon vias 123 may be electrically isolated from other components. The second through silicon vias 123 may function as a heat dissipation structure. In this way, by implementing the second through silicon vias 123 as a heat dissipation structure within the uppermost memory die 120T, heat generated within the memory stack 140 may be dissipated to the outside through the second through silicon vias 123 and a dummy die 150. As a result, a thermal characteristic of the high bandwidth memory (HBM) 100 may be improved.

In FIG. 7, a configuration other than the second through silicon vias 123 of the uppermost memory die 120T is the same as that described in FIGS. 1 and 2. In FIG. 7, the contents described in FIGS. 1 and 2 may be equally applied to the configuration other than the second through silicon vias 123 of the uppermost memory die 120T.

The content describing the arrangement of the connection members 160 in FIG. 3 may be equally applied to the high bandwidth memories (HBMs) 100 described with reference to FIGS. 5 to 7.

Although the example embodiment of the present disclosure has been described above, the present disclosure is not limited thereto, and it is possible to carry out various modifications within the scope of the claims, the detailed description of the disclosure, and the accompanying drawings. Modifications fall within the scope of the present disclosure.

What is claimed is:

1. A high bandwidth memory comprising:
a base die;
a memory stack on the base die, the memory stack including a plurality of stacked memory dies, the memory stack having:
a first region defined by dividing a horizontal plane of the memory stack, and
a second region in the horizontal plane surrounding the first region;
a dummy die on the memory stack; and
a plurality of bumps between the memory stack and the dummy die, the plurality of bumps including:
a plurality of first bumps disposed in the first region, and
a plurality of second bumps disposed in the second region, a pitch of neighboring second bumps among the plurality of second bumps different from a pitch of neighboring first bumps among the plurality of first bumps.

2. The high bandwidth memory of claim 1, wherein:
the pitch of neighboring second bumps among the plurality of second bumps is smaller than the pitch of neighboring first bumps among the plurality of first bumps.

3. The high bandwidth memory of claim 1, wherein:
the pitch of neighboring second bumps among the plurality of second bumps is larger than the pitch of neighboring first bumps among the plurality of first bumps.

4. The high bandwidth memory of claim 1, further comprising:
an insulating layer between the memory stack and the dummy die.

5. The high bandwidth memory of claim 4, wherein:
the insulating layer is a molded under-fill (MUF).

6. The high bandwidth memory of claim 4, wherein:
the insulating layer is a non-conductive film (NCF) or a non-conductive paste (NCP).

7. The high bandwidth memory of claim 4, wherein:
the insulating layer has a vertical thickness of 20 μm to 40 μm.

8. The high bandwidth memory of claim 1, wherein:
the plurality of bumps are electrically isolated from the memory stack.

9. A high bandwidth memory comprising:
a base die;
a memory stack on the base die, the memory stack including a plurality of stacked memory dies and a plurality of interconnection structures alternating with the plurality of stacked memory dies, the memory stack having:
a first region defined by dividing a horizontal plane of the memory stack, and
a second region in the horizontal plane surrounding the first region;
a dummy die on the memory stack;
a plurality of bumps between the memory stack and the dummy die, the plurality of bumps including:
a plurality of first bumps disposed in the first region, and
a plurality of second bumps disposed in the second region, a pitch of neighboring second bumps among the plurality of second bumps different from a pitch of neighboring first bumps among the plurality of first bumps; and
a molding material covering the memory stack, the dummy die, and the plurality of bumps on the base die.

10. The high bandwidth memory of claim 9, wherein:
the base die is a buffer die.

11. The high bandwidth memory of claim 9, wherein:
the plurality of stacked memory dies are dynamic random-access memories (DRAMs).

12. The high bandwidth memory of claim 9, wherein:
the dummy die comprises a silicon material or a conductive material and has no active circuit devices formed therein.

13. The high bandwidth memory of claim 9, wherein:
each of the plurality of interconnection structures includes:
a plurality of first bonding pads;
a first silicon insulating layer surrounding the plurality of first bonding pads;
a plurality of second bonding pads positioned on the plurality of first bonding pads, the plurality of second bonding pads each being directly bonded to a respective one of the plurality of first bonding pads; and
a second silicon insulating layer positioned on the first silicon insulating layer, the second silicon insulating layer surrounding the plurality of second bonding pads and being directly bonded to the first silicon insulating layer.

14. A high bandwidth memory comprising:
a base logic die;
a plurality of core dies stacked on the base logic die, an uppermost core die of the plurality of core dies having:
a first region defined by dividing a horizontal plane of the uppermost core die, and
a second region in the horizontal plane surrounding the first region;
a heat dissipation structure on the uppermost core die;
a plurality of bumps between the uppermost core die and the heat dissipation structure, a plurality of bumps including:
a plurality of first bumps on the first region, and
a plurality of second bumps on the second region, a pitch of neighboring second bumps among the plurality of second bumps different from a pitch of neighboring first bumps among the plurality of first bumps; and
a molding material covering the plurality of core dies, the heat dissipation structure, and the plurality of bumps on the base logic die.

15. The high bandwidth memory of claim 14, wherein:
the uppermost core die among the plurality of core dies includes a plurality of bonding pads, and
each of the plurality of bonding pads is bonded to a respective one of the plurality of bumps.

16. The high bandwidth memory of claim 14, wherein:
core dies other than the uppermost core die among the plurality of core dies include a plurality of through substrate vias, and
the uppermost core die among the plurality of core dies does not include through substrate vias.

17. The high bandwidth memory of claim 14, wherein:
no core dies are above the uppermost core die, and a vertical thickness of the uppermost core die is the same as a vertical thickness of remaining core dies among the plurality of core dies.

18. The high bandwidth memory of claim 14, wherein:
a vertical height from a lower surface of the uppermost core die to an upper surface of the heat dissipation structure is between 100 μm and 200 μm.

19. The high bandwidth memory of claim 14, wherein:
a vertical thickness of the heat dissipation structure is equal to or larger than a vertical thickness of each of the plurality of core dies.

20. The high bandwidth memory of claim 14, wherein:
a horizontal width of the heat dissipation structure is equal to or larger than a horizontal width of each of the plurality of core dies.
